(19) United States
(12) Patent Application Publication
(10) Pub. No.: US 2025/0369149 A1
(43) Pub. Date: Dec. 4, 2025

(54) DEVICE AND METHOD FOR CENTRIFUGALLY SYNTHESIZING AND GROWING COMPOUND CRYSTAL

(71) Applicant: THE 13TH RESEARCH INSTITUTE OF CHINA ELECTRONICS TECHNOLOGY GROUP CORPORATION, Shijiazhuang, Hebei (CN)

(72) Inventors: Shujie Wang, Shijiazhuang, Hebei (CN); Niefeng Sun, Shijiazhuang, Hebei (CN); Senfeng Xu, Shijiazhuang, Hebei (CN); Huimin Shao, Shijiazhuang, Hebei (CN); Zheng Liu, Shijiazhuang, Hebei (CN); Yanlei Shi, Shijiazhuang, Hebei (CN); Jian Jiang, Shijiazhuang, Hebei (CN); Xiaolan Li, Shijiazhuang, Hebei (CN); Yang Wang, Shijiazhuang, Hebei (CN); Junyan Huai, Shijiazhuang, Hebei (CN); Zuobao Sun, Shijiazhuang, Hebei (CN); Xiaodan Zhang, Shijiazhuang, Hebei (CN); Yong Kang, Shijiazhuang, Hebei (CN); Wei Wang, Shijiazhuang, Hebei (CN); Huisheng Liu, Shijiazhuang, Hebei (CN); Yaqi Li, Shijiazhuang, Hebei (CN); Hongfei Zhao, Shijiazhuang, Hebei (CN)

(21) Appl. No.: 18/995,076

(22) PCT Filed: Jul. 13, 2023
(86) PCT No.: PCT/CN2023/107177

§ 371 Date: Jan. 15, 2025

(30) Foreign Application Priority Data
Jul. 15, 2022 (CN) 202210829211.0

(51) Int. Cl. C30B 11/00; C30B 11/06; C30B 27/02

(52) U.S. Cl. CPC C30B 11/008; C30B 11/002; C30B 11/003; C30B 11/065; C30B 27/02

(57) ABSTRACT

A device and method for centrifugally synthesizing and growing a compound crystal, which relate to the field of preparation of compound semiconductors. The device comprises a furnace body and a crucible in the furnace body, wherein a sealing groove is formed in the top of the crucible, a sealing cover matching the sealing groove is provided, and the crucible is connected to a centrifugal electric motor outside the furnace body by means of a crucible rod. The method comprises the steps of placing a raw material, assembling the device, sealing the crucible, performing centrifugal synthesis, and growing a crystal.

### FIELD

The present invention relates to the preparation of compound semiconductors, and more particularly to an apparatus and method for synthesizing and growing compound crystals using a centrifugal device.

### BACKGROUND

The main synthesis methods involving compounds of volatile materials and metals include: solute diffusion synthesis (SSD), horizontal Bridgman method (HB)/horizontal gradient solidification method (HGF), and injection synthesis method. Among them, the injection synthesis method has the highest efficiency and is a method for realizing low-cost, high-quality polycrystalline industrialization. For example, Chinese patent application numbers 202010487276.2, 202110618242.7, 202110618255.4, 202110376836.1, etc. disclose technical solutions for synthesizing compound semiconductor materials using a gas injection device: using a heating injection device, the volatile gas source material is heated and vaporized, and then the vaporized elements are injected into the melt through an injection pipe to complete the synthesis. There is a hidden danger of melt backflow when using the above scheme.

In order to solve the above problems, Chinese patent application 201911155614.6 discloses a technical solution of injecting non-metallic elements outside the furnace, and Chinese patent application 202110760674.1 discloses a solution of placing non-metallic elements in a melt and vaporizing the non-metallic elements at the temperature of the melt, but a special device is still required to provide the non-metallic materials required for synthesis, and the equipment composition is complex.

### SUMMARY

The purpose of the present invention is to simplify the device for synthesizing compound crystals and eliminate the hidden dangers caused by the injection device.

To achieve the above-mentioned purpose, the present invention adopts the following technical scheme:
A device for centrifugal synthesis and growth of compound crystals, comprising a furnace body, a crucible in the furnace body, and a crucible support, wherein the crucible includes a main crucible and a main heater on the periphery of the main crucible, an auxiliary crucible arranged at the center of the bottom of the main crucible, and a first auxiliary heater on the periphery of the auxiliary crucible. The key points are:
The crucible also includes a sealing groove arranged on the top of the crucible, the sealing groove is annular, and a second auxiliary heater is arranged on the periphery of the sealing groove;
The crucible support is connected to a centrifugal motor outside the furnace body through a crucible rod;
The device also includes a sealing cover paired with the sealing groove, the sealing cover is connected to an auxiliary rod I through a mechanical arm, and the auxiliary rod I is connected to a sealing cover driving device outside the furnace body.

Further, the device also includes a loader arranged inside the furnace body, and the loader is connected to the loader driving device outside the furnace body through an auxiliary rod II.

Further, the device also includes a seed crystal sieve arranged on the top of the furnace body.

Based on the above device, the present invention also discloses a method for centrifugal synthesis and growth of compound crystals, comprising the following steps:
Step 1: Place the solid metal element in the main crucible and make it lean against the side wall of the main crucible, place the volatile element in the auxiliary crucible, place the sealing material in the sealing groove, and place the crucible in the crucible support.
Step 2, after sealing the furnace body, evacuate the entire system to 50-10⁻⁵ Pa; heat the sealing material in the sealing groove through the second auxiliary heater until it melts, and then use the auxiliary rod I to send the sealing cover into the sealing groove; reduce the power of the second auxiliary heater to solidify the sealing material and achieve a sealed state;
   start the mechanical arm to separate the auxiliary rod I from the sealing cover.
Step 3, the centrifugal motor drives the crucible rod to rotate the crucible support and the crucible, the rotation rate n≤5500 (pr)^{-0.5}, p is the density of the melt, r is the diameter of the main crucible where the diameter of the main crucible is the maximum, so that the solid metal elements are attached to the side wall of the main crucible under the action of centrifugal force;
   the main crucible is heated by the main heater until the temperature reaches 30-200° C. above the melting temperature of the compound semiconductor material to be synthesized, and the metal elements are melted and confined to the side wall of the main crucible to form a cylindrical shape.
Step 4, using the first auxiliary heater to heat the volatile element to 10-100° C. above its triple point, during the heating process, inert gas is continuously charged into the system to keep the pressure inside and outside the crucible basically the same;
   the volatile element is sublimated into gas and then synthesized with the melted metal element;
   the temperature is kept constant at 10-100° C. above the triple point for 2 m hours to 10 m hours, and the synthesis is completed; m is the mass number of the metal material in kg.
Step 5, reduce the rotation speed of the crucible rod to 0; gradually reduce the power of the main heater and the first auxiliary heater to room temperature, and make the melt solidify into a solid, and gradually make the inside of the furnace body normal pressure.
Step 6, heat the sealing material in the sealing groove to melt by the second auxiliary heater, and then start the mechanical arm to combine the auxiliary rod I and the sealing cover, and then through the rise and rotation of the auxiliary rod I, the sealing cover is separated from the sealing groove and away from the crucible.

Further, after the compound is synthesized, crystal growth is achieved in situ using the liquid seal Czochralski method (LEC) or the vertical gradient method (VGF).

Beneficial effects: When the device and method proposed in the present invention are used, there is no injection device for volatile elements, which simplifies the synthesis equipment and eliminates the hidden dangers of melt backflow to the injection device and explosion of the injection device. The present invention only increases the rotation speed of the rotating system of the crucible, which has the characteristics of simplicity, economy, energy saving and high efficiency; before heating, the metal material is attached to the side wall of the crucible under the action of centrifugal force, which is closer to the main heater and has higher heating efficiency for the metal; two groups of heaters heat the metal and the volatile elements respectively, and the two do not affect each other; during the synthesis, the volatile elements will not escape and all participate in the synthesis, eliminating waste; all materials are loaded before the compound is generated, and external contamination is reduced; further technical means can realize the in-situ growth of crystals to improve efficiency.

### BRIEF DESCRIPTION OF THE DRAWINGS

FIG. 1 is a schematic diagram of the composition of an embodiment of the device of the present invention;

FIG. 2 is a schematic diagram of the composition of another embodiment of the device of the present invention;

FIG. 3 is a state diagram of the device during compound synthesis;

FIG. 4 is a schematic diagram of crystal growth by the LEC method;

FIG. 5 is a schematic diagram of the crucible;

FIG. 6 is another state diagram of the device during compound synthesis;

FIG. 7 is a schematic diagram of crystal growth by the VGF method.

Wherein: 1: crucible; 1-1: sealing groove; 1-3: main crucible; 1-4: auxiliary crucible; 2: main heater; 3: metal element; 4: crucible support; 5: first auxiliary heater; 6: second auxiliary heater; 7: crucible support; 8: volatile element; 9: auxiliary rod I; 10: sealing cover; 11: mechanical arm; 12: auxiliary support II; 12-1: oxide loader; 13: oxide cover; 14: seed crystal rod; 15: seed crystal; 16: sealing material; 17: furnace body; 18: crystal; 19: melt; 20: seed crystal, 21: centrifugal motor; 22: crystal; 23: Liquid oxide.

### DETAILED DESCRIPTION

The present invention is further described below in conjunction with the accompanying drawings.

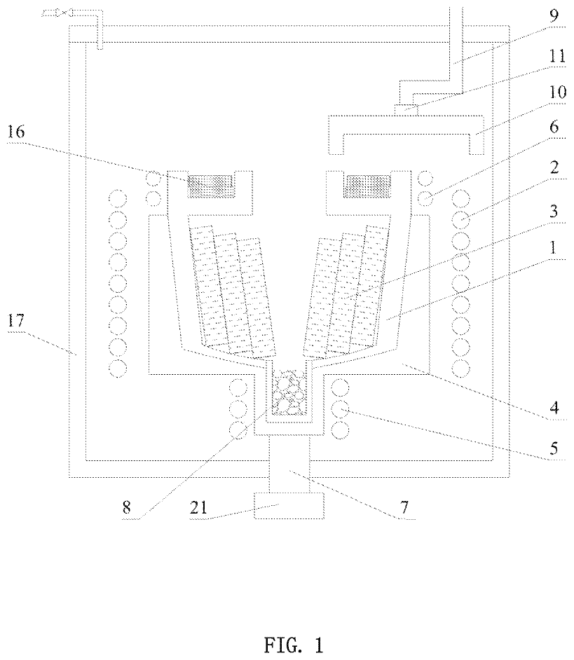

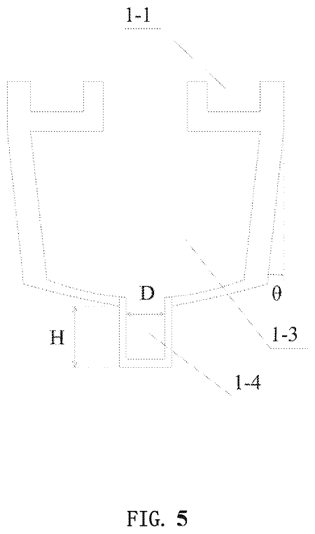

Referring to FIG. 1 and FIG. 5, a device for centrifugally synthesizing and growing compound crystals includes a furnace body 17, a crucible 1 and a crucible support 4 in the furnace body 17. The crucible 1 includes a main crucible 1-3 and a main heater 2 on the periphery of the main crucible 1-3, an auxiliary crucible 1-4 arranged at the center at the bottom of the main crucible 1-3, and a first auxiliary heater 5 on the periphery of the auxiliary crucible 1-4.

The crucible 1 also includes an annular sealing groove 1-1 arranged on the top of the crucible 1, and a second auxiliary heater 6 is arranged on the periphery of the sealing groove 1-1; the crucible support 4 is connected to a centrifugal motor 21 outside the crucible body 17 through a crucible support 7.

The device also includes a sealing cover 10 paired with the sealing groove 1-1, and the sealing cover 10 is connected to the auxiliary rod 19 through the mechanical arm 11, and the auxiliary rod 19 is connected to the sealing cover driving device outside the furnace body 17 (not shown in the figure).

The diameter of the auxiliary crucible (1-4) is 10-30 mm, ensuring that the height can meet the requirements of loading the volatile elements 8 required for synthesis.

The above device can realize the synthesis of compounds.

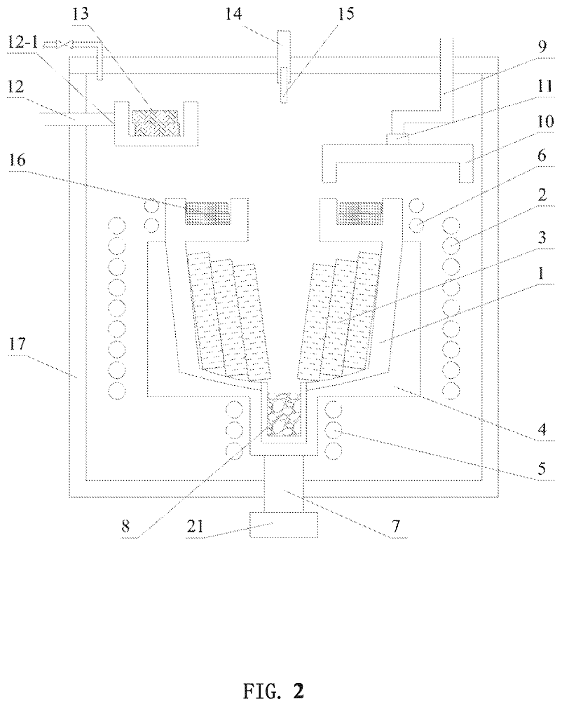

When growing crystals, referring to FIG. 2, the device further includes a loader 12-1 disposed inside the furnace body 17, and the loader 12-1 is connected to a loader driving device (not shown) outside the furnace body 1) via an auxiliary rod II 12. The device further includes a seed crystal rod 14 disposed on the top of the furnace body 17.

In addition, the side wall of the main crucible 1-3 is not set vertically, and the angle between the side wall of the main crucible 1-3 and the vertical direction is θ and the range of θ is 2-10°. The purpose of this design is to make it easy for the melt to form a cylinder under centrifugal force, and at the same time, after the centrifugal force is removed, the melt can flow smoothly to the bottom of the crucible.

### Compound Generation

The following embodiment is to use the above device to complete the synthesis of the compound.

Step 1, place the solid metal element 3 in the main crucible 1-3 and make it lean on the side wall of the main crucible 1-3, place the volatile element 8 in the auxiliary crucible 1-4, place the sealing material 16 in the sealing groove 1-1, and place the crucible 1 in the crucible support 4 to complete the loading, see FIG. 2.

The number of metal elements 3 and volatile elements 8 placed is related. After determining the number of metal elements 3, the number of volatile elements 8 can be calculated according to the chemical reaction formula.

Step 2, after sealing the furnace body 17, evacuate the entire system to 50-10⁻⁵ Pa; The sealing material 16 in the sealing groove 1-1 is heated to harden by the second auxiliary heater 6, and then the sealing cover 10 is sent into the sealing groove 1-1 by the auxiliary rod 19 and immersed in the melted sealing material 16; the power of the second auxiliary heater 6 is reduced to solidify the sealing material 16, and the sealing state is achieved; the sealing material 13 is an alloy material or an oxide material with a melting point of 800-1300° C., and the sealing cover 10 is “welded” to the crucible 1 through the sealing material 16;

The mechanical arm 11 is started to separate the auxiliary rod 19 from the sealing cover 10.

Step 3, drive the cylinder rod 7 through the centrifugal motor 21 to rotate the crucible support 4 and the crucible 1, the rotation rate n≤5500 (pr)^{-0.5}, p is the density of the melt 19, r is the diameter of the main crucible 1-3 where the diameter of the main crucible is the maximum, so that the solid metal element 3 is attached to the side wall of the main crucible 1-3 under the action of centrifugal force.

At this time, the metal material 3 in the main crucible 1-3 has not hardened. After the metal material 3 is hardened, it combines with the volatile element 8 to form the melt 19.

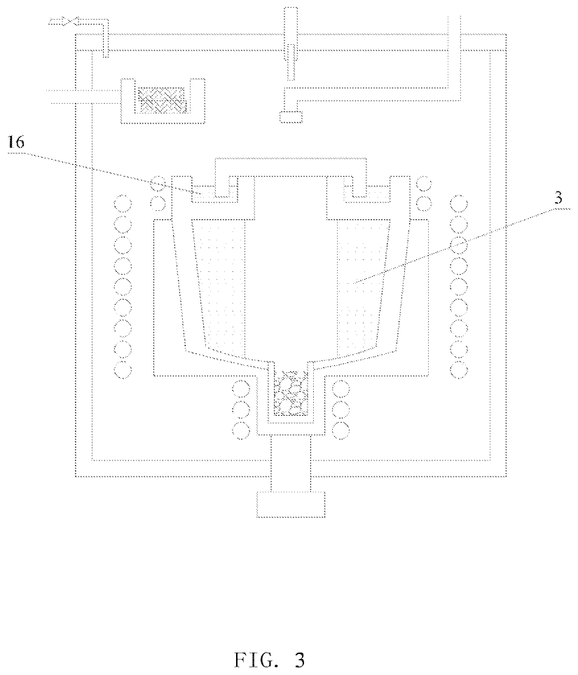

The main crucible 1-3 is heated by the main heater 2 until the temperature reaches 30-200° C. above the melting temperature of the compound semiconductor material to be synthesized. The metal element 3 is melted and confined on the side wall of the main crucible 1-3 to form a cylindrical shape, see FIG. 3.

Generally speaking, the melting point of semiconductor compounds is higher than the melting point of the metal material that forms the compound, e.g., the melting point of steel: 156.51° C., the melting point of phosphated steel: 1070° C., the melting point of gallium: 1238° C., and the melting point of gallium: 29.76° C. Under the above conditions, the metal material 3 will melt.

At this time, the center of the main crucible 1-3 is empty, which can provide space for the volatile element 8.

Step 4, use the first auxiliary heater 5 to heat the volatile element 8 to 10-100° C. above its double phase point, and continuously fill the system with inert gas during the heating process to keep the pressure inside and outside the crucible basically the same.

The triple point refers to the temperature and pressure value in thermodynamics that allows a substance to coexist in three phases (gas phase, liquid phase, solid phase).

For example, the triple point of phosphorus is about 590° C. Above the triple point, phosphorus can sublime relatively quickly.

At this time, the crucible 1 is sealed, but there are volatile elements in it that are gasified, causing the pressure inside and outside the crucible 1 to be unbalanced. The role of filling inert gas is to ensure that the crucible will not be damaged by the pressure difference. The crucible has a certain pressure bearing capacity. Within its bearing range, the crucible will not be damaged, so it is not required that the pressure inside and outside are completely equal.

During the heating process, the internal pressure can be calculated based on the density in the crucible, and then the amount of inert gas required to maintain pressure balance can be known.

After the volatile element 8 is sublimated into gas, it is synthesized with the melted metal element 3.

The synthesis is completed at a constant temperature of 10-100° C. above the triple point for 2 m hours to 10 m hours; where m is the mass number of the metal material 3 in kg.

The synthesis time of different compounds is different and is related to the synthesis quantity. The synthesis time is the time to ensure the completion of compound synthesis. The synthesis time of 2 m hours to 10 m hours should be adjusted according to different compounds and experience.

Step 5. After the synthesis is completed, reduce the rotation speed of the crucible rod 7 to 0; gradually reduce the power of the main heater 2 and the first auxiliary heater 5 to room temperature, so that the melt solidifies into a solid. At the same time, by means of filling and releasing inert gas, gradually make the inside of the furnace body 17 normal pressure.

Step 6. Heat the sealing material 16 in the sealing groove 1-1 through the second auxiliary heater 6 until it hardens, and then start the mechanical arm 11 to combine the auxiliary rod I 9 with the sealing cover 10, and then through the rise and rotation of the auxiliary rod I 9, the sealing cover 10 is separated from the sealing groove 1-1 and away from the crucible 1.

The temperature inside the crucible is reduced to room temperature. At this time, if there are any volatile elements remaining, they will no longer volatilize, and the gas inside the crucible is very small.

In the above process, if the pressure inside and outside the crucible is unbalanced and the sealing cover 10 cannot be moved, the furnace body 17 is evacuated to reduce the internal pressure until the sealing cover 10 is away from the crucible.

The above process completes the synthesis of the compound.

The liquid-sealed Czochralski method (LEC) is used to achieve crystal growth.

In order to achieve in-situ growth of crystals, in step 1, in addition to the aforementioned loading process, the seed crystal 15 is fixed on the seed crystal rod 14, and the oxide film 13 is placed in the oxide film loader 12-1.

After step 6 is completed, the following steps are added:
Step 7, put the oxide 13 into the main crucible 1-3 through the auxiliary rod II 12, and then move it away from the crucible 1 to above the crucible 1;
Increase the power of the main heater 2 and the first auxiliary heater 5, and melt the compound polycrystalline material and the oxide 13 into a melt 19 and liquid oxide 23 again, and the liquid oxide 23 covers the melt 19 to become a sealant;
By adjusting the power of the main heater 2 and the first auxiliary heater 5, a suitable grade gradient is established in the melt 19.

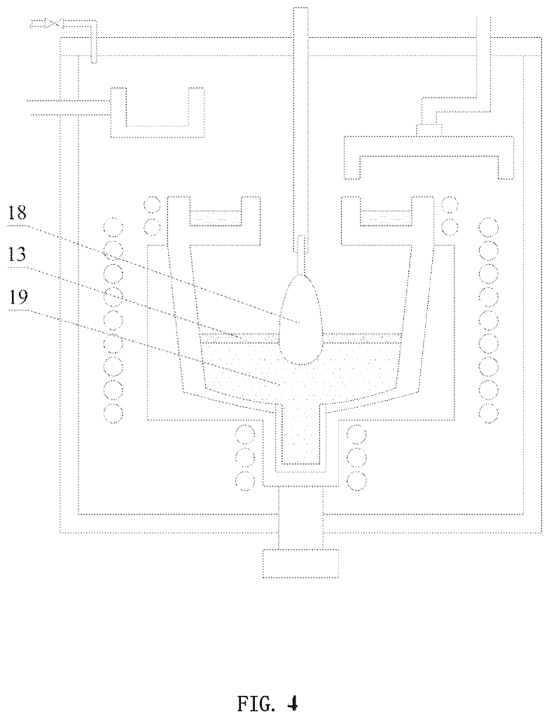

Step 8, lower the seed crystal rod 14 so that the seed crystal (15) enters the main crucible 1-3 and contacts the melt 19, then adjust the power of the main heater 2 and the first auxiliary heater 5 again, find the crystallization point of the compound melt, and perform liquid-sealed Czochralski (LEC) crystal growth by pulling the seed crystal rod 14, see FIG. 4.

The crystal 18 can also be annealed by the main heater 2 to reduce its stress and dislocation density.

Step 9, after the growth is completed, slowly lower the temperature until the crystal 18 cools, pull the crystal 18 out of the crucible 1, dismantle the furnace, and take out the crystal 18.

Vertical temperature gradient method (VGF) is used to achieve crystal growth.

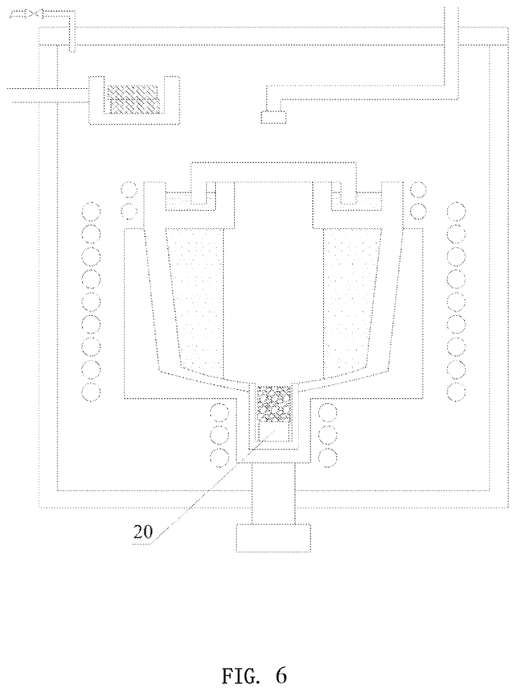

Similarly, in order to achieve in-situ growth of crystals, in step 1, in addition to the aforementioned charging process, the volatile element 8 and the seed crystal 20 are simultaneously placed in the auxiliary crucible 1-4, and the seed crystal 20 is placed below the volatile element 8; the oxide chamber 13 is placed in the oxide loader 12-1, see FIG. 6.

After step 6 is completed, the following steps are added:
Step 10, put the oxide 13 into the main crucible 1-3 through the auxiliary rod II 12, and then move it away from the crucible 1 to the top of the crucible 1;
Increase the power of the main heater 2 and the first auxiliary heater 5, and melt the compound polycrystalline material and the oxide 13 into a melt 19 and liquid oxide 23 again, and the liquid oxide 23 covers the melt 19 to become a sealant; make the temperature of the seed crystal 20 in the auxiliary crucible 1-4 always lower than the melting point of the compound semiconductor material;
By adjusting the power of the main heater 2 and the first auxiliary heater 5, melt part of the seed crystal 20, and establish a suitable temperature gradient in the melt 19.

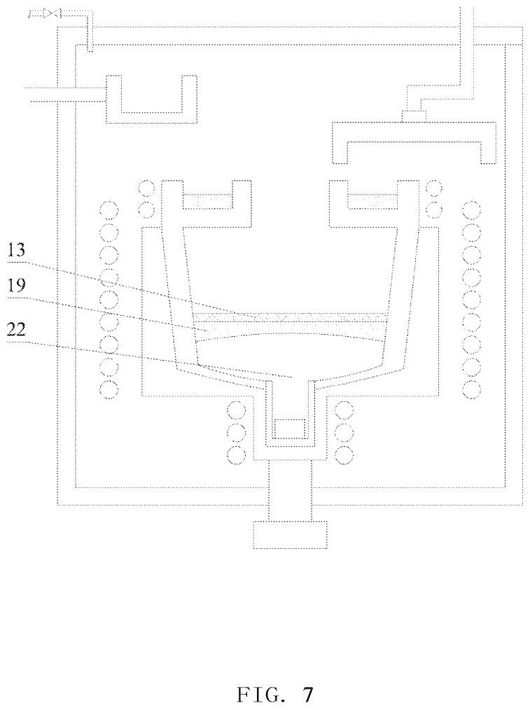

Step 11, gradually reduce the power of the main heater 2 and the first auxiliary heater 5 to perform vertical temperature gradient method (VGF) crystal growth, see FIG. 7.

The crystal 22 can be annealed by the main heater 2 to reduce its stress and dislocation density.

Step 12, after the growth is completed, slowly reduce the quality until the crystal 22 cools, dismantle the furnace, and take out the crystal 22.

1. A device for centrifugal synthesis and growth of compound crystals, comprising a furnace body, a crucible and a crucible support in the furnace body, wherein the crucible comprises a main crucible and a main heater on the periphery of the main crucible, an auxiliary crucible arranged at the center of the bottom of the main crucible, and a first auxiliary heater on the periphery of the auxiliary crucible, wherein:
the crucible further comprises a sealing groove arranged on the top of the crucible, the sealing groove is annular, and a second auxiliary heater is arranged on the periphery of the sealing groove;
the crucible support is connected through a crucible rod to a centrifugal motor outside of the furnace body;
the device also includes a sealing cover paired with the sealing groove, the sealing cover is connected to the auxiliary rod I through the mechanical arm, and the auxiliary rod I is connected to the sealing cover driving device outside the furnace body.

2. The device for centrifugally synthesizing and growing compound crystals according to claim 1, characterized in that the device further comprises a loader arranged inside the furnace body, and the loader is connected to a loader driving device outside the furnace body via an auxiliary rod II.

3. The device for centrifugally synthesizing and growing compound crystals according to claim 1, characterized in that the device further comprises a seed crystal rod arranged on the top of the furnace body.

4. The device for centrifugally synthesizing and growing compound crystals according to claim 1, characterized in that the angle between the side wall of the main crucible and a vertical direction is 2-10°.

5. The device for centrifugal synthesis and growth of compound crystals according to claim 1, characterized in that the diameter of the auxiliary crucible is 10-30 mm.

6. A method for centrifugally synthesizing and growing compound crystals, which is implemented based on the device for centrifugally synthesizing and growing compound crystals as described in claim 5, wherein the method comprises the following steps:
Step 1, placing a solid metal element in the main crucible and making it lean against the side wall of the main crucible, placing a volatile element n the auxiliary crucible, placing a sealing material in the sealing groove, and placing the crucible in the crucible support;
Step 2, after sealing the furnace body, evacuating the entire system to 50-10⁻⁵ Pa;
heating the sealing material in the sealing groove by a second auxiliary heater until it melts, and then using an auxiliary rod I to cover the sealing cover into the sealing groove; reducing the power of the second auxiliary heater to solidify the sealing material and making the crucible in a sealed state;
starting the mechanical arm to separate the auxiliary rod I from the sealing cover;
Step 3, driving the crucible rod through the centrifugal motor to rotate the crucible support and the crucible, with a rotation speed n≤5500 (pr)^{-0.5}, p is the density of the melt, r is the diameter of the main crucible where the diameter of the main crucible is at the maximum, so that the solid metal element is attached to the side wall of the main crucible under the action of centrifugal force;
heating the main crucible with the main heater, until the temperature is 30-200° C. above the melting point of the compound semiconductor material to be synthesized; after the metal element melts, confining it to a side wall of the main crucible to form a cylindrical shape;
Step 4, using the first auxiliary heater to heat the volatile element to 10-100° C. above its double phase point; during the heating process, inert gas is continuously introduced into the system to keep a pressure inside and outside the crucible basically equal;
after the volatile element sublimates into gas, it is synthesized with the melted metal element;
maintaining a temperature at a constant temperature of 10-100° C. above the triple point for 2 m hours to 10 m hours, and the synthesis is completed; wherein m is the mass number of the metal material in kg;
Step 5, reducing the rotation speed of the crucible rod to 0; gradually reducing a power of the main heater and the first auxiliary heater to room temperature; and making the melt solidified into a solid, and at the same time, gradually bringing the inside of the furnace body to normal pressure;
Step 6, heating the sealing material in the sealing groove to melt by the second auxiliary heater, and then starting the mechanical arm to make the auxiliary rod I and the sealing cover combined, and then raising and rotating the auxiliary rod I to separate the sealing cover from the sealing groove and away from the crucible.

7. The method for centrifugal synthesis and growth of compound crystals according to claim 6 is characterized in that:
in step 1, the seed crystal is fixed on the seed crystal rod, and boron oxide is placed in a boron oxide loader;
after step 6 is completed, the following steps are added:
step 7, the boron oxide is put into the main crucible through the auxiliary rod II, and then the boron oxide is moved away from the crucible;
the power of the main heater and the first auxiliary heater is increased, and the compound polycrystalline material and the boron oxide are melted into a melt and a liquid boron oxide, and the liquid boron oxide covers the melt to become a sealant;
by adjusting the power of the main heater and the first auxiliary heater, establishing a suitable temperature gradient in the melt;
step 8, lowering the seed crystal rod so that the seed crystal enters the main crucible and contacts the melt, then adjusting the power of the main heater and the first auxiliary heater again to find the crystallization point of the compound melt, and perform liquid-sealed Czochralski (LEC) crystal growth by pulling the seed crystal rod;
annealing the crystal (18) through the main heater to reduce its stress and dislocation density;
step 9, after the growth is completed, slowly cooling down until the crystal is cooled, pulling the crystal out of the crucible, dismantling the furnace, and taking out the crystal.

8. The method for centrifugal synthesis and growth of compound crystals according to claim 6 is characterized in that:
in step 1, the volatile element and the seed crystal are placed in the auxiliary crucible at the same time, and the seed crystal is located below the volatile element; the boron oxide is placed in the boron oxide loader;
after step 6 is completed, the following steps are added:
step 10, the boron oxide is put into the main crucible through the auxiliary rod II, and then it is moved away from the crucible;
the power of the main heater and the first auxiliary heater is increased, and the compound polycrystalline material and the boron oxide are melted into a melt and a liquid boron oxide, and the liquid boron oxide covers a top of the melt as a sealant;
marking the temperature of the seed crystal in the auxiliary crucible always lower than the melting point of the compound semiconductor material; by adjusting the power of the main heater and the first auxiliary heater, part of the seed crystal is melted, and a suitable temperature gradient is established in the melt;
step 11, gradually reducing the power of the main heater and the first auxiliary heater to perform vertical grade gradient method (VGF) crystal growth;
annealing the crystal through the main heater to reduce its stress and dislocation density;
step 12, after the growth is completed, slowly cooling down until the crystal is cooled, dismantling the furnace, and taking out the crystal.
